(19) United States
(12) Patent Application Publication
(10) Pub. No.: US 2024/0404805 A1
(43) Pub. Date: Dec. 5, 2024

(54) PLASMA PROCESSING APPARATUS, CONTROL METHOD, AND STORING MEDIUM

(71) Applicant: Tokyo Electron Limited, Minato-ku, Tokyo (JP)

(72) Inventors: Mikio SATO, Nirasaki City, Yamanashi (JP); Eiki KAMATA, Nirasaki City, Yamanashi (JP); Taro IKEDA, Nirasaki City, Yamanashi (JP); Nobuhiko YAMAMOTO, Osaka City, Osaka (JP)

(21) Appl. No.: 18/690,810

(22) PCT Filed: Sep. 5, 2022
(86) PCT No.: PCT/JP2022/033247

§ 371 Date: Mar. 11, 2024

(30) Foreign Application Priority Data
Sep. 17, 2021 (JP) 2021-152599

(51) Int. Cl. H01J 37/32

(52) U.S. Cl. CPC H01J 37/3299; H01J 37/32449; H01J 37/32926; H01J 37/32981; H01J 2237/332; H01J 2237/334

(57) ABSTRACT

A plasma processing apparatus includes a control device and configured to plasmarize a gas supplied to an interior of a processing container to perform a plasma processing on an object to be processed, wherein the control device includes: a measurer configured to measure an electron energy distribution function of plasma in the interior of the processing container, and a parameter changer configured to change parameters relating to the plasma processing so that the electron energy distribution function measured by the measurer during the plasma processing approaches a target electron energy distribution function.

### TECHNICAL FIELD

The present disclosure relates to a plasma processing apparatus, a control method, and a program.

### BACKGROUND

For example, in a plasma processing apparatus, it is known that an electron energy distribution function (EEDF) of plasma inside a chamber varies depending on a process recipe, a chamber status, or the like. In order to optimize plasma processing (plasma process), for example, the EEDF of the plasma inside the chamber needs to be close to an ideal form.

In the related art, an information processing device that determines a predetermined processing condition for a process treatment to be performed on a workpiece by inputting initial state data of the workpiece and target end state data of the workpiece has been known. In such an information processing apparatus, performing a machine learning to improve the efficiency of searching for an optimal solution is disclosed. In addition, a plasma density is described as an example of data relating to semiconductor manufacturing process treatment (for example, see Patent Document 1).

### PRIOR ART DOCUMENT

### Patent Document

Patent Document 1: International Publication No. 2019/155928

The present disclosure provides a technique for controlling an electron energy distribution function of plasma inside a processing container to approach a target electron energy distribution function by changing parameters relating to plasma processing.

### SUMMARY

According to one embodiment of the present disclosure, a plasma processing apparatus comprises a control device and configured to plasmarize a gas supplied to an interior of a processing container to perform a plasma processing on an object to be processed, wherein the control device includes a measurer configured to measure an electron energy distribution function of plasma in the interior of the processing container, and a parameter changer configured to change a parameter relating to the plasma processing so that the electron energy distribution function measured by the measurer during the plasma processing approaches a target electron energy distribution function.

According to the present disclosure, it is possible to provide a technique for controlling an electron energy distribution function of plasma inside a processing container to approach a target electron energy distribution function by changing parameters relating to plasma processing.

### BRIEF DESCRIPTION OF DRAWINGS

FIG. 1 is an exemplary cross-sectional view of a plasma processing apparatus according to an embodiment of the present disclosure.

FIG. 2 shows a hardware configuration of an example of a computer.

FIG. 3 is a diagram showing an example of a functional configuration of a control device according to an embodiment.

FIG. 4 is a flowchart showing an example of a processing procedure performed by the plasma processing apparatus according to the embodiment.

FIG. 5 is an explanatory view of an example of an ideal electron energy distribution function of plasma.

FIG. 6A is an explanatory view of examples of evaluation functions

FIG. 6B is an explanatory view of examples of the evaluation functions FIG. 6C is an explanatory view of examples of the evaluation functions FIG. 6D is an explanatory view of examples of the evaluation functions FIG. 7 is a view showing an example of a probability distribution (prior distribution) of a value of each coefficient in a learning model.

FIG. 8 is an explanatory view of an example of a process of measuring an electron energy distribution function of plasma inside a processing container during plasma processing.

FIG. 9 is an explanatory view of an example of a process of changing a process parameter.

FIG. 10A is an explanatory view of an example of an evaluation result of the electron energy distribution function of the plasma during the plasma processing, which varies due to a change in process parameters.

FIG. 10B is an explanatory view of an example of the evaluation result of the electron energy distribution function of the plasma during the plasma processing, which varies due to the change in process parameters.

FIG. 11 is an explanatory view of an example of the evaluation result of the electron energy distribution function of the plasma during the plasma processing, which varies due to the change in process parameters.

FIG. 12 is an explanatory view of an example in which a control rule is updated.

FIG. 13 is an explanatory view of an example in which a probability distribution (prior distribution) of a value of each coefficient in a learning model that defines the control rule is updated.

FIG. 14A is an explanatory view of an example in which the probability distribution (prior distribution) of the value of each coefficient in the learning model that defines the control rule is updated.

FIG. 14B is an explanatory view of an example in which the probability distribution (prior distribution) of the value of each coefficient in the learning model that defines the control rule is updated.

FIG. 14C is an explanatory view of an example in which the probability distribution (prior distribution) of the value of each coefficient in the learning model that defines the control rule is updated.

FIG. 15A is an explanatory view of an example of a process of repeatedly controlling the electron energy distribution function of the plasma by repeating learning of the control rule.

FIG. 15B is an explanatory view of an example of the process of repeatedly controlling the electron energy distribution function of the plasma by repeating learning of the control rule.

FIG. 15C is an explanatory view of an example of the process of repeatedly controlling the electron energy distribution function of the plasma by repeating learning of the control rule.

FIG. 15D is an explanatory view of an example of the process of repeatedly controlling the electron energy distribution function of the plasma by repeating learning of the control rule.

### DETAILED DESCRIPTION

Embodiments of the present disclosure will now be described with reference to the accompanying drawings. In this specification and drawings, illustrations and descriptions of portions that are not necessary for the descriptions of the embodiments will be omitted as appropriate.

### [Plasma Processing Apparatus]

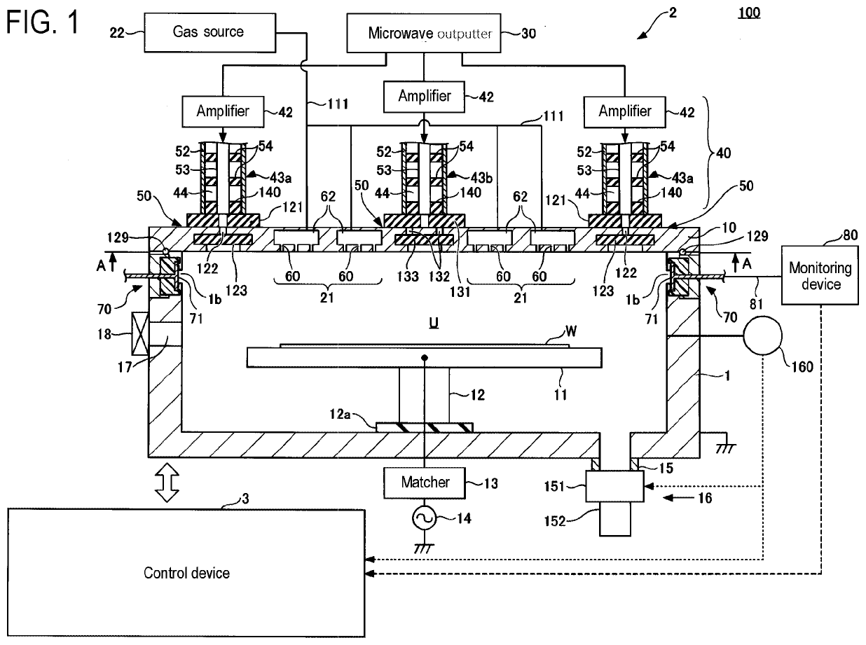

FIG. 1 is an exemplary cross-sectional view of a plasma processing apparatus according to an embodiment of the present disclosure. A plasma processing apparatus 100 includes a processing container (chamber) 1 that accommodates a wafer W. The plasma processing apparatus 100 performs plasma processing on the wafer W using surface wave plasma formed on an inner wall surface of a ceiling portion of the processing container 1 by microwaves. The plasma processing includes film formation processing, etching processing, or ashing processing.

The plasma processing apparatus 100 includes the processing container 1, a microwave plasma source 2, and a control device 3. The processing container 1 is a substantially cylindrical airtight container made of a metal material, such as aluminum or stainless steel, and is grounded.

The processing container 1 includes a main body 10 and has a plasma processing space formed therein. The main body 10 is a disc-shaped ceiling plate that constitutes the ceiling portion of the processing container 1. A support ring 129 is provided on a contact surface between the processing container 1 and the main body 10. An interior of the processing container 1 is airtightly sealed. The main body 10 is formed of a metal material such as aluminum or stainless steel.

The microwave plasma source 2 includes a microwave outputter 30, a microwave transmitter 40, and a microwave radiation mechanism 50. The microwave outputter 30 outputs microwaves to a plurality of divided paths. The microwaves are introduced into the processing container 1 via the microwave transmitter 40 and the microwave radiation mechanism 50. Gas supplied to the interior of the processing container 1 is excited by an electric field of the introduced microwaves so that surface wave plasma is formed.

A stage 11 on which the wafer W is placed is provided inside the processing container 1. The stage 11 is supported by a support member 12 of a cylindrical shape which is provided to stand on the center of the bottom of the processing container 1 with an insulating member 12a interposed between the stage 11 and the support member 12. Examples of materials constituting the stage 11 and the support member 12 include a metal, such as aluminum, the surface of which is alumite-treated (anodized), or an insulating member (ceramic and the like) having high-frequency electrodes provided therein. The stage 11 may be provided with an electrostatic chuck for electrostatically adsorbing the wafer W, a temperature control mechanism, a gas flow path for supplying heat transfer gas to a back surface of the wafer W, and the like.

A radio-frequency bias power supply 14 is connected to the stage 11 via a matcher 13. When radio frequency power is supplied from the radio-frequency bias power supply 14 to the stage 11, ions in plasma are attracted toward the wafer W. The radio-frequency bias power supply 14 may be omitted according to characteristics of the plasma processing.

An exhaust port is provided in the bottom of the processing container 1. An exhaust pipe 15 is connected to the exhaust port. The exhaust pipe 15 is connected to an exhaust device 152 via a pressure control valve 151. The exhaust pipe 15, the pressure control valve 151, and the exhaust device 152 constitute a gas exhauster 16. The exhaust device 152 includes a vacuum pump such as a turbomolecular pump.

The interior of the processing container 1 is exhausted when the gas exhauster 16 is operated, and is decompressed at high speed to a predetermined level of vacuum. Further, a pressure gauge 160 is installed in the processing container 1. The pressure gauge 160 measures an internal pressure value of the processing container 1. A measurement result measured by the pressure gauge 160 is received by the control device 3. Further, the pressure control valve 151 controls a degree of opening thereof based on the measured internal pressure value.

A sidewall of the processing container 1 is provided with a loading/unloading port 17 for loading/unloading the wafer W therethrough, and a gate valve 18 for opening/closing the loading/unloading port 17. The microwave transmitter 40 transmits the microwaves output from the microwave outputter 30. A central microwave introducer 43b in the microwave transmitter 40 is arranged at the center of the main body 10. Six peripheral microwave introducers 43a are arranged around the main body 10 at equal intervals in a circumferential direction. The central microwave introducer 43b and the six peripheral microwave introducers 43a have the function of introducing microwaves output from amplifiers 42 shown in FIG. 1, which are provided in a correspondence relationship with the central microwave introducer 43b and the six peripheral microwave introducers 43a, into the microwave radiation mechanism 50, and an impedance matching function. Hereinafter, the peripheral microwave introducers 43a and the central microwave introducer 43b may be collectively referred to as a microwave introducer 43.

Six dielectric layers 123 are arranged below the six peripheral microwave introducers 43a and inside the main body 10. Further, one dielectric layer 133 is arranged below the central microwave introducer 43b and inside the main body 10. The number of the peripheral microwave introducers 43a and the number of the dielectric layers 123 are not limited to six and may be two or more, respectively. Specifically, the number of the peripheral microwave introducers 43a and the number of the dielectric layers 123 may three or more, respectively. As an example, the number of the peripheral microwave introducers 43a and the number of the dielectric layers 123 may be three to six.

The microwave radiation mechanism 50 in FIG. 1 includes a dielectric ceiling plate 121, a dielectric ceiling plate 131, a slot 122, a slot 132, a dielectric layer 123, and a dielectric layer 133. The dielectric ceiling plates 121 and 131 are formed of disc-shaped dielectrics that transmit microwaves, and are arranged on an upper surface of the main body 10. The dielectric ceiling plates 121 and 131 are formed of quartz, ceramics such as alumina (Al₂O₃), fluorine-based resin such as polytetrafluoroethylene, or polyimide-based resin, which has a relative dielectric constant higher than a vacuum. As a result, a wavelength of the microwaves transmitted through the dielectric ceiling plates 121 and 131 is made shorter than that of microwaves propagating in a vacuum, which makes it possible to reducing the size of an antenna including the slots 122 and 132.

Below the dielectric ceiling plates 121 and 131, the dielectric layers 123 and 133 are in contact with a back surface of an opening of the main body 10 via the slots 122 and 132 formed in the main body 10. The dielectric layers 123 and 133 are formed of, for example, quartz, ceramics such as alumina (Al₂O₃), fluorine-base resin such as polytetrafluoroethylene, or polyimide-based resin. The dielectric layers 123 and 133 are provided at positions depressed from the ceiling surface by a thickness of the opening formed in the main body 10 and function as dielectric windows that supply the microwaves to a plasma generation space U.

Each of the peripheral microwave introducers 43a and the central microwave introducer 43b is arranged in a coaxial relationship with a cylindrical outer conductor 52 and a rod-shaped inner conductor 53 provided at the center of the outer conductor 52. A gap between the outer conductor 52 and the inner conductor 53 functions as a microwave transmission path 44 to which the microwave power is supplied and through which the microwaves propagate toward the microwave radiation mechanism 50.

Each of the peripheral microwave introducers 43a and the central microwave introducer 43b is provided with a slug 54 and an impedance adjustment member 140 located at a tip of the slug 54. By moving the slug 54, an impedance of load (plasma) inside the processing container 1 is matched with a characteristic impedance of a microwave power source in the microwave outputter 30. The impedance adjustment member 140 is made of a dielectric material and is configured to adjust an impedance of the microwave transmission path 44 based on a dielectric constant of the dielectric material.

The main body 10 is provided with a gas introducer 21 having a shower structure. Gas supplied from a gas source 22 is supplied to the interior of the processing container 1 in the form of a shower via the gas introducer 21 from a gas diffusion chamber 62 via a gas supply pipe 111. The gas introducer 21 is an example of, for example, a gas shower head that supplies a gas from a plurality of gas supply holes 60 formed in a ceiling wall of the processing container 1. Examples of the gas may include a gas for plasma generation such as an Ar gas, a gas to be decomposed with high energy, such as an O₂ gas or a N₂ gas, and a processing gas such as a silane gas.

An opening 1b is formed in a sidewall of the processing container 1 in a circumferential direction, and a plasma probe device 70 is attached to the opening 1b. The number of plasma probe devices 70 attached to the processing container 1 may be one or more. The plasma probe device 70 senses plasma generated in the plasma generation space U.

The plasma probe device 70 is connected to a monitoring device 80. The monitoring device 80 includes a signal transmitter and outputs a signal of a predetermined frequency transmitted by the signal transmitter. The output signal of a predetermined frequency is transmitted to the plasma probe device 70 via a coaxial cable 81 and is transmitted from an antenna portion 71 at a tip of the plasma probe device 70 toward the plasma.

The plasma probe device 70 detects a current value from the side of the plasma with respect to the signal transmitted toward the plasma and transmits the detected current value to the monitoring device 80. The detected current value is transmitted from the monitoring device 80 to the control device 3. The control device 3 measures an electron energy distribution function (EEDF) of the plasma inside the processing container 1 by, for example, FFT (frequency) analysis. In this way, the control device 3 measures the EEDF in the plasma inside the processing chamber 1 from frequency characteristics of the plasma generation space U obtained by electrical probe measurement. Details of the plasma probe device 70 and the monitoring device 80 are disclosed in, for example, Japanese Patent Laid-Open Publication No. 2019-046787.

Each part of the plasma processing apparatus 100 is controlled by the control device 3. The control device 3 controls each part of the plasma processing apparatus 100 based on a process sequence and a process recipe of the plasma processing apparatus 100. Further, the control device 3 may display inputs or results when performing a predetermined control according to the process sequence and the process recipe. The control device 3 may be built in the plasma processing apparatus 100 or may be connected to the plasma processing apparatus 100 via a communication path.

The communication path may use a wired communication scheme or a wireless communication scheme and may be any signal path for exchanging various signals inside and outside a computer. The communication path may use a network such as a local area network (LAN).

In order to perform the plasma processing in the plasma processing apparatus 100, the wafer W is loaded into the processing chamber 1 via the loading/unloading port 17 from the gate valve 18 in an open state while being held by a transfer arm. After the wafer W is loaded, the gate valve 18 is closed. When the wafer W is transferred to an upper portion of the stage 11, the wafer W is moved from the transfer arm to pusher pins and then the pusher pins are lowered so that the wafer W is placed on the stage 11. An internal pressure of the processing container 1 is maintained at a predetermined level of vacuum by the gas exhauster 16. Gas is introduced into the processing container 1 from the gas introducer 21 in the form of a shower. The microwaves radiated from the microwave radiation mechanism 50 via the peripheral microwave introducers 43a and the central microwave introducer 43b propagate on the inner surface of the ceiling wall. The gas is excited by an electric field of the microwaves that propagate as surface waves. The wafer W is subjected to the plasma processing by surface wave plasma generated in the plasma generation space U under the ceiling wall on the side of the processing chamber 1.

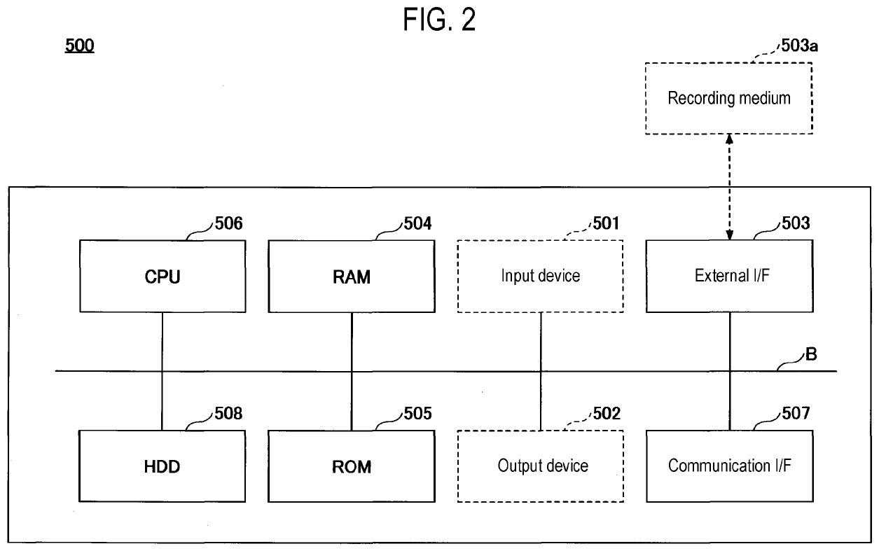

The control device 3 is implemented by, for example, a computer 500 of FIG. 2. The control device 3 reads a program recorded in a storage device and executes the plasma processing by transmitting and receiving various signals to and from respective parts constituting the plasma processing apparatus 100 according to the program.

The control device 3 is implemented by a computer with a hardware configuration, for example, as shown in FIG. 2. FIG. 2 shows the hardware configuration of an example of the computer.

The computer 500 of FIG. 2 includes an input device 501, an output device 502, an external interface (I/F) 503, a random access memory (RAM) 504, a read only memory (ROM) 505, a central processing unit (CPU) 506, a communication I/F 507, a hard disk drive (HDD) 508 and the like, which are is interconnected via a bus B. The input device 501 and the output device 502 may be used by being connected to each other as necessary.

The input device 501 is a keyboard, a mouse, a touch panel, or the like, and is used by an operator or the like to input various operation signals. The output device 502 is a display or the like and displays results processed by the computer 500 thereon. The communication I/F 507 is an interface that connects the computer 500 to a network or the like. The HDD 508 is an example of a nonvolatile storage device that stores programs or data.

The external I/F 503 is an interface with an external device. The computer 500 reads out data from and/or writes data to a recording medium 503a such as a secure digital (SD) memory card via the external I/F 503. The ROM 505 is an example of a nonvolatile semiconductor memory (storage device) in which programs or pieces of data are stored. The RAM 504 is an example of a volatile semiconductor memory (storage device) that temporarily stores programs or pieces of data.

The CPU 506 is an arithmetic device that implements control and functions of the entire computer 500 by reading out the programs or the pieces of data from a storage device such as the ROM 505 or the HDD 508 on the RAM 504 to execute processing.

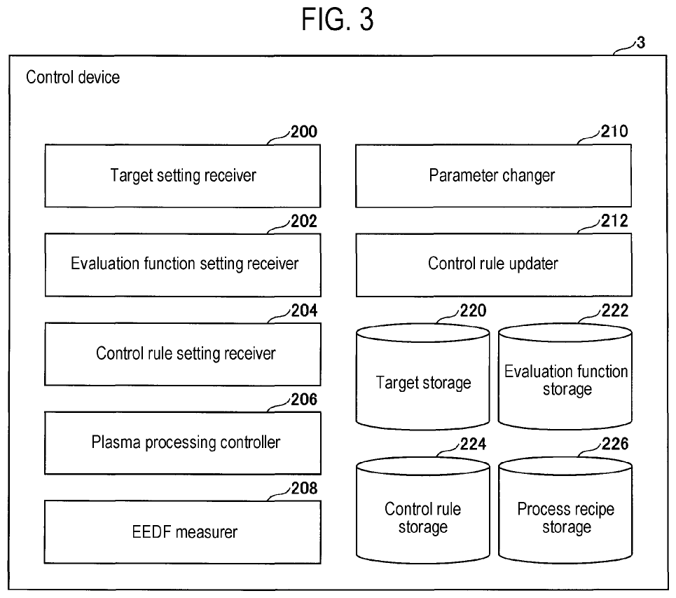

The control device 3 shown in FIG. 1 may implement various functions shown in FIG. 3 by allowing the computer 500 having the hardware configuration shown in FIG. 2 to execute the processing according to the program.

FIG. 3 is a diagram showing an example of functional configurations of the control device according to an embodiment. The control device 3 shown in FIG. 3 includes a target setting receiver 200, an evaluation function setting receiver 202, a control rule setting receiver 204, a plasma processing controller 206, an electron energy distribution function measurer 208, a parameter changer 210, a control rule updater 212, a target storage 220, an evaluation function storage 222, a control rule storage 224, and a process recipe storage 226.

The target setting receiver 200 receives a setting of a target electron energy distribution function of plasma from an operator or the like. The target electron energy distribution function of plasma is an electron energy distribution function of plasma that is considered to be ideal in a desired plasma processing (plasma process).

Such an ideal electron energy distribution function of plasma may be determined through experimentation, calculation, literature research, or the like. For example, the ideal electron energy distribution function of plasma may be determined based on the purpose of plasma processing, a chemical reaction within plasma, and the like. Further, the ideal electron energy distribution function of plasma may be determined from a correlation between measurement results of the electron energy distribution function of plasma and evaluation results of a process such as film quality.

In addition to the setting of the ideal electron energy distribution function of plasma corresponding to the desired plasma processing, the target setting receiver 200 may also receive a setting of an ideal electron energy distribution function of plasma corresponding to a certain location inside the processing container 1. Further, the target setting receiver 200 may receive a setting of an ideal electron energy distribution function of plasma that does not vary according to the lapse of time of the plasma processing or a setting of an ideal electron energy distribution function of plasma that varies according to the lapse of time of the plasma processing.

For example, the ideal electron energy distribution function of plasma may be defined by Equation 1 below. In Equation 1, x is an example of an element that determines a form of the electron energy distribution function. T_{eff} is an example of an element that determines a spread condition of the electron energy distribution function.

$${f}_{EEDF} ( ε , x , {T}_{eff} ) = {g}_{x} \sqrt{ε} exp ( - {c}_{x} {ε}^{x} ) \\ {g}_{x} ≡ \frac{{x [ 2 Γ ( 5 / 2 x ) / 3 {T}_{eff} ]}^{3 / 2}}{{[ Γ ( 3 / 2 x ) ]}^{5 / 2}} , {c}_{x} ≡ {[ 2 Γ ( 5 / 2 x ) / 3 {T}_{eff} Γ ( 3 / 2 x ) ]}^{x} \qquad [ Equation 1 ]$$

x: parameter that determines the form of the electron energy distribution function (EEDF) (which is Maxwell distribution for x=1 and Druyvesteyn distribution for x=2)
T_{eff}: effective electron temperature
ε: electron energy
Γ: gamma function (special function that extends the concept of factorial to all complex numbers and real numbers)

Further, the evaluation function setting receiver 202 receives, from an operator or the like, a setting of an evaluation function that quantifies a similarity or discrepancy between the electron energy distribution function of plasma measured during the plasma processing and the target electron energy distribution function of plasma.

For example, the evaluation function that quantifies the discrepancy between the electron energy distribution function of plasma measured during the plasma processing and the target electron energy distribution function of plasma may be defined by Equation 2 below. In Equation 2, exp denotes a measurement result, and ideal denotes an ideal form.

$$h = [ \begin{matrix}{h}_{1} \\ {h}_{2}\end{matrix} ] ≡ [ \begin{matrix}Δ x \\ Δ {T}_{eff}\end{matrix} ] = [ \begin{matrix}{x}_{exp} - {x}_{ideal} \\ {T}_{eff , exp} - {T}_{eff , ideal}\end{matrix} ] \qquad [ Equation 2 ]$$

Equation 2 shows an example of the evaluation function that quantifies the discrepancy between the electron energy distribution function of plasma measured during the plasma processing and the target electron energy distribution function of plasma by a vector h defined by the difference between the measurement result of x and T_{eff} and the ideal form. For example, since plasma is thought to vary greatly in quality depending on whether high-energy electrons are excessive or low-energy electrons are excessive, the evaluation function of Equation 2 may be considered to be more desirable than an evaluation function of the sum of squares of residuals.

Further, the control rule setting receiver 204 receives, from an operator or the like, a setting of an initial learning model which represents a correspondence between parameters relating to the plasma processing and a result of the evaluation function. For example, the control rule setting receiver 204 receives a setting of an initial learning model hᵢ=Φᵢ (θ₁, θ₂, . . . , θ_{M}) representing the vector h by M process parameters {θ₁, θ₂, . . . , θ_{M}}.

The process parameters are examples of the parameters relating to the plasma processing, such as an input power, a frequency of input power, a duty ratio of an input power pulse, a gas mixture ratio, a pressure, a temperature, a cumulative number of processes, a recent process recipe, a recently-measured electron energy distribution function, and the like. A form of the learning model and each coefficient in the learning model define a control rule.

When there are two process parameters (M=2), the control rule setting receiver 204 may receive a setting of the learning model such as Equation 3 below.

$${Φ}_{i} = {a}_{1} + {a}_{2} {θ}_{1} + {a}_{3} {θ}_{2} + {a}_{4} {θ}_{1}^{2} + {a}_{5} {θ}_{2}^{2} + {a}_{6} {θ}_{1} {θ}_{2} + {a}_{7} {θ}_{1}^{2} {θ}_{2} + {a}_{8} {θ}_{1} {θ}_{2}^{2} + … \qquad [ Equation 3 ]$$

The learning model, the setting of which is received by the control rule setting receiver 204, may be determined through experimentation, calculation, literature research, and the like. The learning model, the setting of which is received by the control rule setting receiver 204, is an initial learning model, which is learned by repeating the plasma processing and updated to obtain accuracy, as will be described later. Further, the control rule setting receiver 204 expresses, by a range estimate value as described later, a probability distribution (prior distribution) of a value of each coefficient in the learning model that defines the control rule. The range estimate value is expressed as a normal distribution centered on, for example, a point estimate value. The probability distribution of the value of each coefficient in the learning model that defines the control rule, may be expressed to depict shading of a probability p(a) in a space having a vector a, for example, as shown in Equation 4 below.

$$Vector a = [ \begin{matrix}{a}_{1} \\ {a}_{2} \\ {a}_{3} \\ ⋮\end{matrix} ] \qquad [ Equation 4 ]$$

The plasma processing controller 206 controls the plasma processing apparatus 100 so that the plasma processing is performed according to process parameters. The electron energy distribution function measurer 208 measures the electron energy distribution function of plasma in the processing container 1 during the plasma processing. The electron energy distribution function measurer 208 may measure the electron energy distribution function of plasma using an existing insulation probe method that is applicable to the plasma process.

For example, the electron energy distribution function measurer 208 may derive the electron energy distribution function of plasma in the processing chamber 1 from frequency characteristics of the plasma generation space U obtained by electrical probe measurement.

The parameter changer 210 evaluates the electron energy distribution function of plasma, which is a measurement result obtained by the electron energy distribution function measurer 208, according to the evaluation function set in the evaluation function setting receiver 202. For example, the parameter changer 210 quantifies the discrepancy between the electron energy distribution function of plasma, which is the measurement result, and the target electron energy distribution function of plasma, which is set in the evaluation function setting receiver 202.

The parameter changer 210 changes the process parameters so that the electron energy distribution function of plasma, which is the measurement result, approaches the target electron energy distribution function of plasma, according to a learning model that expresses the correspondence between the process parameters and the results of the evaluation function. The process parameters may include changeable (controllable) parameters and unchangeable parameters. The input power, the frequency of input power, the duty ratio of input power pulse, the gas mixture ratio, the pressure, and the temperature are examples of the changeable parameters. The cumulative number of processes, the recent process recipe, and the recently-measured electron energy distribution function are examples of the unchangeable parameters.

The control rule updater 212 updates the learning model based on the evaluation result of the electron energy distribution function of plasma during the plasma processing using the process parameters changed by the parameter changer 210. The control rule updater 212 updates each coefficient in the learning model using a response of the electron energy distribution function of plasma due to a change in the process parameters as a new information source.

When the evaluation result of the electron energy distribution function of plasma during the plasma processing using the process parameters changed by the parameter changer 210 is not as expected, the control rule updater 212 determines that the accuracy of the learning model is poor (the control rule is incorrect). When the evaluation result of the electron energy distribution function of plasma during the plasma processing using the process parameters changed by the parameter changer 210 is as expected, the control rule updater 212 determines that the accuracy of the learning model is good (the control rule is correct). When the accuracy of the learning model is determined to be poor, the control rule updater 212 updates each coefficient in the learning model using the response of the electron energy distribution function of plasma due to the change in the process parameters as the new information source. In addition, the control rule updater 212 updates the probability distribution of the value of each coefficient in the learning model that defines the control rule.

During the plasma processing, the control device 3 repeats changing the process parameters by the parameter changer 210 and updating the learning model by the control rule updater 212 so that the electron energy distribution function of plasma during the plasma processing approaches the target electron energy distribution function of plasma. As a result, the control device 3 may control the electron energy distribution function of plasma to be close to the ideal form in order to improve the accuracy of control of the electron energy distribution function of plasma.

The target storage 220 stores the target electron energy distribution function of plasma, the setting of which is received by the target setting receiver 200. The evaluation function storage 222 stores the evaluation function, the setting of which is received by the evaluation function setting receiver 202. The control rule storage 224 stores the initial learning model, the setting of which is received by the control rule setting receiver 204, and the learning model updated by the control rule updater 212. The process recipe storage 226 stores the process sequence and the process recipe.

### [Processing]

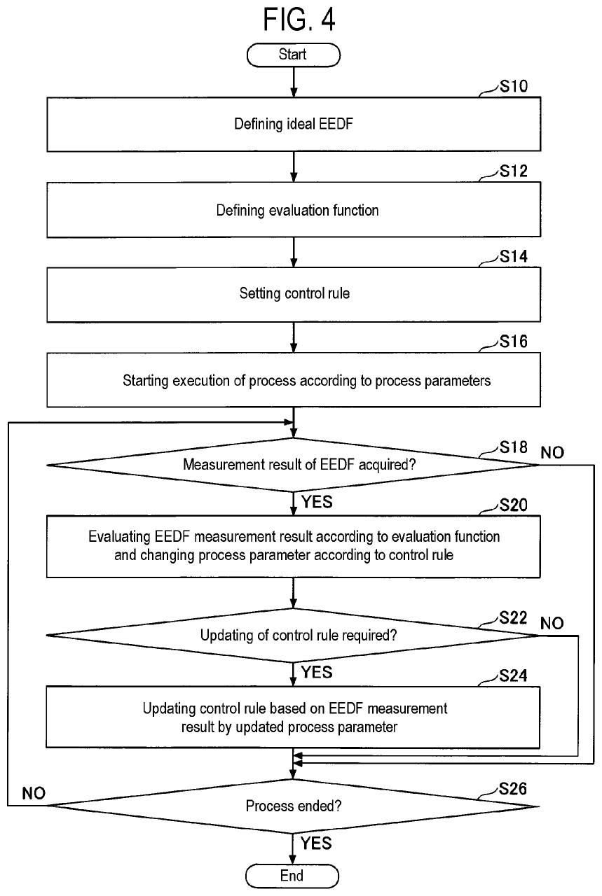

FIG. 4 is a flowchart showing an example of a processing procedure of the plasma processing apparatus according to an embodiment. The flowchart of FIG. 4 shows a process of controlling an effective electron energy distribution function of plasma by the control device 3 among processes of the plasma processing apparatus 100.

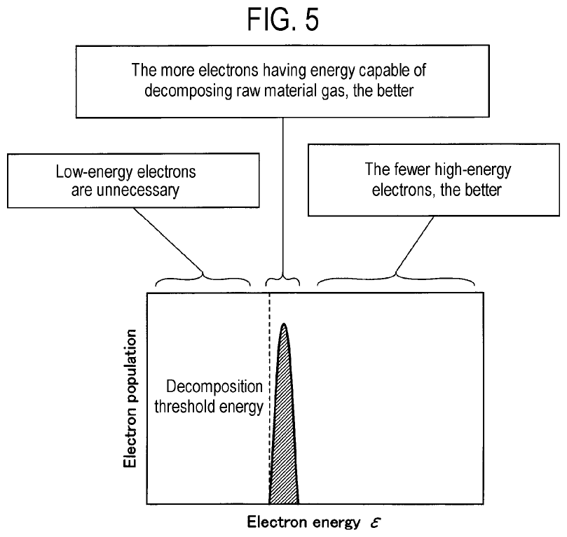

In step S10, the target setting receiver 200 of the control device 3 receives, from the operator or the like, the setting of the target electron energy distribution function of plasma defined by, for example, the above-described Equation 1. The target setting receiver 200 may receive the setting of the target electron energy distribution function of plasma as shown in FIG. 5.

FIG. 5 is an explanatory view of an example of the ideal electron energy distribution function of plasma. The ideal electron energy distribution function of plasma of FIG. 5 shows an example in which there are many electrons with energy that can decompose a material gas and there are no electrons with lower energy than the energy that can decompose the material gas and electrons with higher energy than the energy that may decompose the material gas.

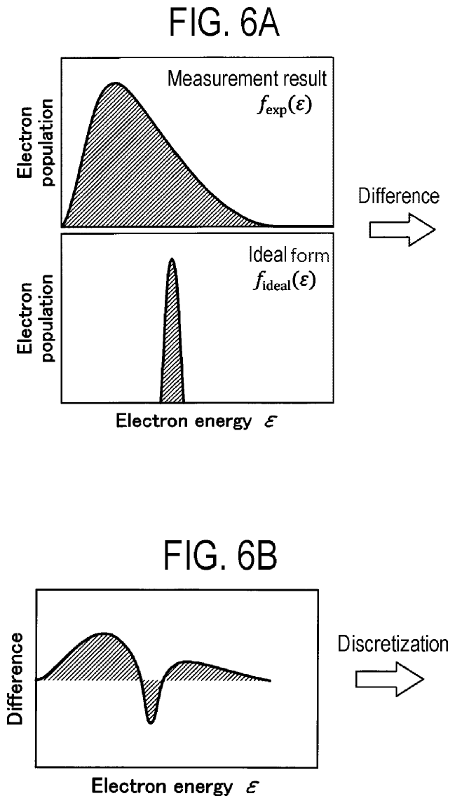

In step S12, the evaluation function setting receiver 202 receives, from the operator or the like, the setting of the evaluation function defined, for example, as shown in FIGS. 6A to 6D. FIGS. 6A to 6D are explanatory views of an example of the evaluation function. The evaluation function shown in FIGS. 6A to 6D quantifies an extent to which the electron energy distribution function of plasma measured during the plasma processing (the electron energy distribution function of the measurement result) is similar to or deviates from the target electron energy distribution function of plasma (the ideal electron energy distribution function).

FIG. 6A shows examples of the electron energy distribution function of the measurement result and the ideal electron energy distribution function. FIG. 6B shows a difference between the electron energy distribution function of the measurement result and the ideal electron energy distribution function shown in FIG. 6A. FIG. 6C shows an example in which the difference shown in FIG. 6B is discretized. The fineness of discretization may be appropriately adjusted and does not necessarily have to be at equal intervals. FIG. 6D shows an example visually representing a discretized difference vector h shown in FIG. 6C. The discretized difference vector h may be expressed by a portion to be prioritized using a weight or the like. For example, in FIG. 6D, a portion corresponding to electrons with high energy is expressed as an integer multiple in order to strictly evaluate the electrons with high energy.

In step S14, the control rule setting receiver 204 receives, from the operator or the like, the setting of the initial learning model representing the correspondence between the process parameters and the result of the evaluation function. For example, the control rule setting receiver 204 receives the setting of the initial learning model hᵢ=Φᵢ (θ₁, θ₂, . . . , θ_{M}) representing the vector h expressed in, for example, Equation 5 by M process parameters {θ₁, θ₂, . . . , θ_{M}}.

$$Vector h = [ \begin{matrix}{h}_{1} \\ {h}_{2} \\ ⋮ \\ {h}_{n}\end{matrix} ] \qquad [ Equation 5 ]$$

Further, the control rule setting receiver 204 expresses a probability distribution (prior distribution) of a value of each coefficient in the learning model that defines the control rule by a range estimate value, for example, as shown in FIG. 7. FIG. 7 is a view showing an example of the probability distribution (prior distribution) of the value of each coefficient in the learning model. FIG. 7 shows an example of the prior distribution of coefficients a₁ to a₃ of the learning model shown in Equation 3. When the number of coefficients is n, the probability distribution of the value of each coefficient in the learning model that defines the control rule is represented to depict shading of a probability p(a) in an n-dimensional space having a vector a, for example, as shown in FIG. 7.

In step S16, the plasma processing controller 206 controls the plasma processing apparatus 100 so that the plasma processing is executed according to the process parameters. The electron energy distribution function measurer 208 measures the electron energy distribution function of plasma in the processing container 1 during the plasma processing every predetermined time (for example, 1 second).

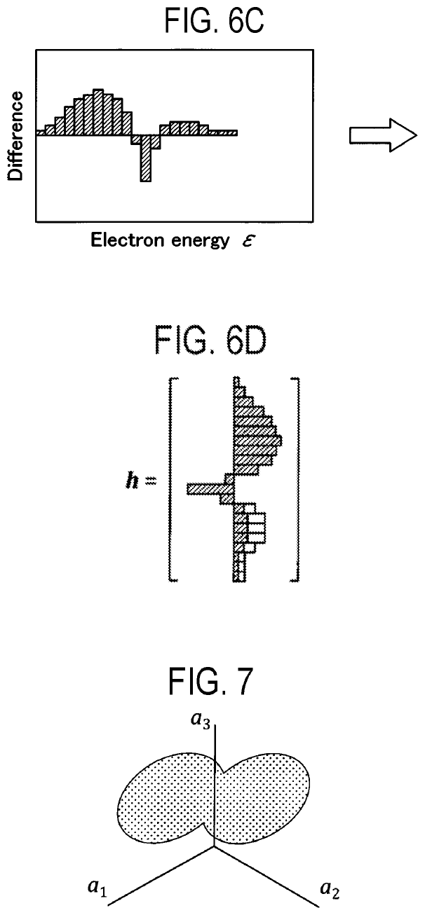

FIG. 8 is an explanatory view of an example of a process of measuring the electron energy distribution function of plasma in the processing container during the plasma processing. A graph showing a sheath rectification characteristic in FIG. 8 represents a relationship between a probe voltage and a probe current. The vertical axis represents the sum of electron current and ionic current flowing into a probe. By positive and negative voltages applied to the probe, the probe measures electrons and ions in plasma attracted into the probe as a current value.

The electron energy distribution function measurer 208 may derive the electron energy distribution function of plasma in the processing chamber 1 from frequency characteristics obtained by FFT-interpreting the probe current measured by the probe.

In step S18, after obtaining the measurement result of the electron energy distribution function of plasma in the processing container 1 during the plasma processing, the control device 3 performs a process of step S20. Further, when the measurement result of the electron energy distribution function of plasma in the processing container 1 during the plasma processing in step S18 is not obtained, the control device 3 skips processes of steps S20 to S24 and performs a process of step S26.

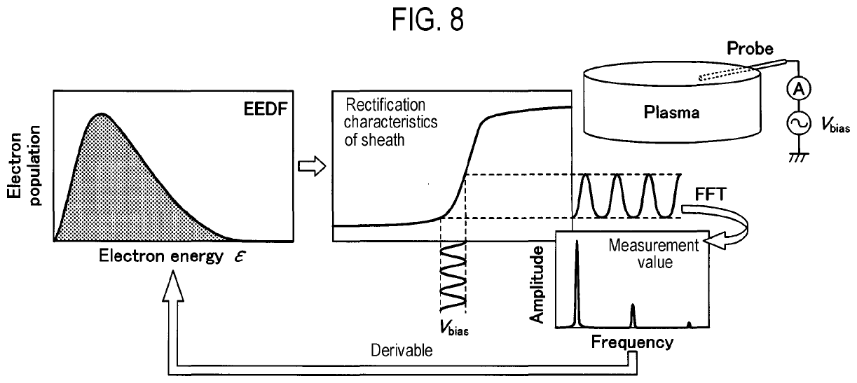

In step S20, the parameter changer 210 evaluates the electron energy distribution function of plasma, which is the obtained measurement result, according to the evaluation function set in the evaluation function setting receiver 202. The parameter changer 210 calculates a process parameter θ′ that gives a vector h′ of a minimum value, for example, as shown in FIG. 9, according to the learning model showing the correspondence between the process parameter and the result of the evaluation function. FIG. 9 is an explanatory view of an example of a process of changing the process parameter. The parameter changer 210 changes the process parameter from θ to θ′. The plasma processing controller 206 controls the plasma processing apparatus 100 so that the plasma processing is executed according to the changed process parameter θ′.

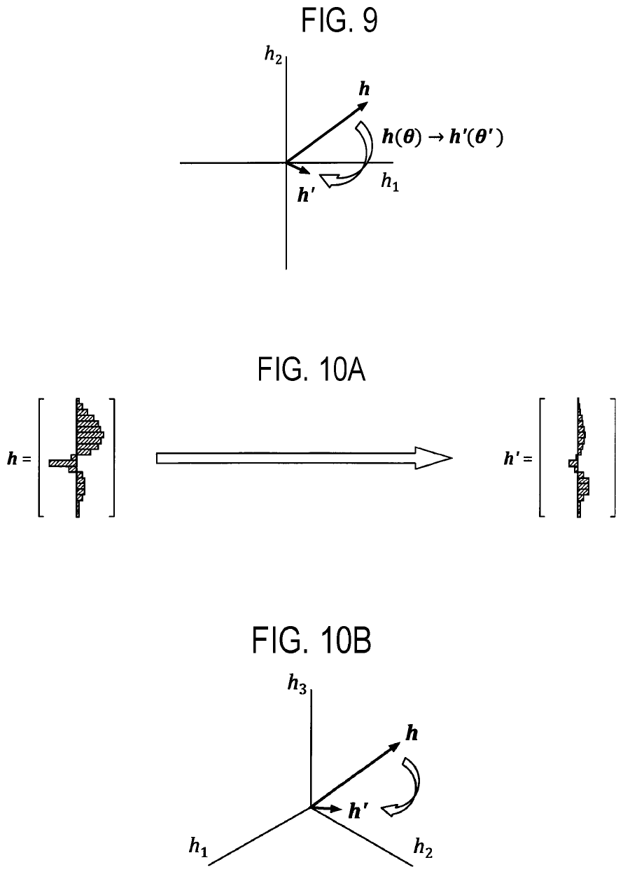

For example, when the accuracy of the learning model is high, the evaluation result of the electron energy distribution function of plasma during the plasma processing using the process parameter θ′ changed by the parameter changer 210 is as expected, as shown in FIGS. 10A and 10B. FIGS. 10A and 10B are explanatory views of an example of the evaluation result of the electron energy distribution function of plasma during the plasma processing, which varies due to a change in process parameter.

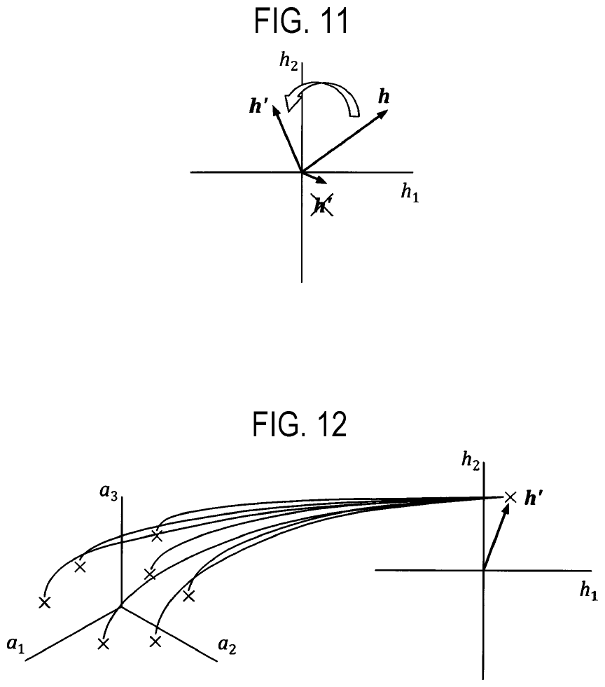

On the other hand, when the accuracy of the learning model is low, the evaluation result of the electron energy distribution function of plasma during the plasma processing using the process parameter θ′ changed by the parameter changer 210 is not as expected, as shown in FIG. 11. FIG. 11 is an explanatory view of an example of the evaluation result of the electron energy distribution function of plasma during the plasma processing, which varies due to the change in process parameter. In FIG. 11, the evaluation result of the electron energy distribution function of plasma during the plasma processing using the changed process parameter θ′ is not as expected, and a direction and norm of the vector h′ are not as expected.

Therefore, the control device 3 updates the control rule in steps S22 to S24 based on the evaluation result of the electron energy distribution function of plasma during the plasma processing using the changed process parameter θ′.

In step S22, the control rule updater 212 determines whether or not the updating of the learning model is required based on the evaluation result of the electron energy distribution function of plasma during the plasma processing using the process parameter θ′ changed by the parameter changer 210. For example, when the accuracy of the learning model is low, the control rule updater 212 determines that the learning model needs to be updated.

When the learning model is determined to need to be updated, the control rule updater 212 performs the process of step S24. When the learning model is determined to not need to be updated, the control rule updater 212 skips the process of step S24.

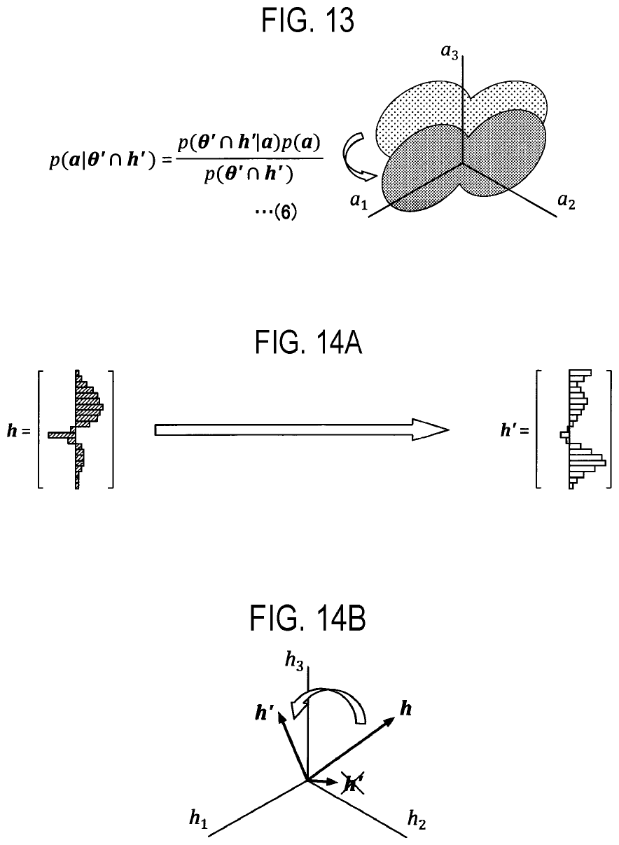

In step S24, the control rule updater 212 updates each coefficient in the learning model, for example, as shown in FIG. 12, based on the evaluation result of the electron energy distribution function of plasma during the plasma processing using the changed process parameter θ′. FIG. 12 is an explanatory view of an example in which the control rule is updated.

For example, even if the process parameter θ′ is specified, as shown in FIG. 12, there are multiple combinations of coefficients (vector a) in the learning model that have the possibility of implementing a vector h′ shown in FIG. 12. For example, for hᵢ=a_{i,1}+a_{i,2}θ, a combination implemented by (θ′, h′ᵢ)=(1, 1) is all (a_{i,1}, a_{i,2}) satisfying a_{i,1}+a_{i,2}=1.

Therefore, in order to implement the update of the most probable vector a, the control rule updater 212 updates the probability distribution (prior distribution) of the value of each coefficient in the learning model that defines the control rule as shown in Equation 6 below according to Bayes' theorem.

$$p ( a \vert {θ}^{′} ⋂ {h}^{′} ) = \frac{p ( {θ}^{′} ⋂ {h}^{′} \vert a ) p ( a )}{p ( {θ}^{′} ⋂ {h}^{′} )} \qquad [ Equation 6 ]$$

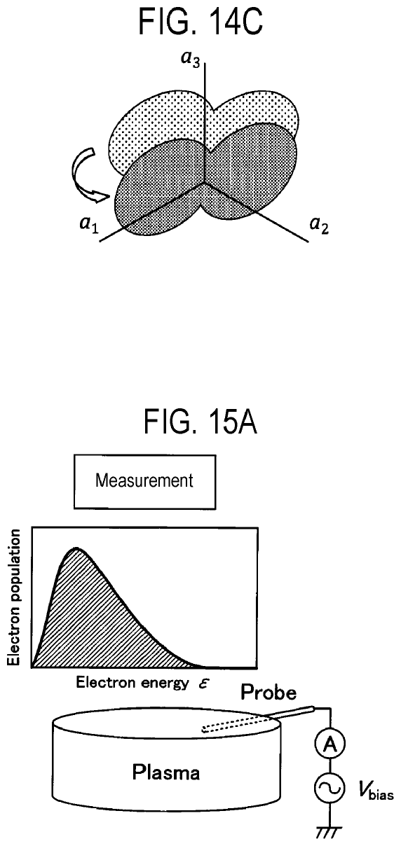

FIG. 13 is an explanatory view of an example in which the probability distribution (prior distribution) of the value of each coefficient in the learning model that defines the control rule is updated. Bayes' theorem is to calculate “a probability P(A|B) of an event A under the condition that an event B has occurred” based on “a probability P(B|A) of the event B under the condition that the event A has occurred”.

In FIG. 13, the probability distribution (posterior distribution) of the value of each coefficient in the learning model is calculated under the condition that an event θ′∩h′ has occurred using a probability p(θ′∩h′|a) of the event θ′∩h′ under the condition of an event a which is the probability distribution (prior distribution) of the value of each coefficient in the learning model.

In this way, the control rule updater 212 re-depicts the probability distribution (prior distribution) of the value of each coefficient in the learning model that defines the control rule as a posterior distribution based on the event θ′∩h′. The value of each coefficient in the learning model that defines the control rule may select, for example, the most probable values from the posterior distribution.

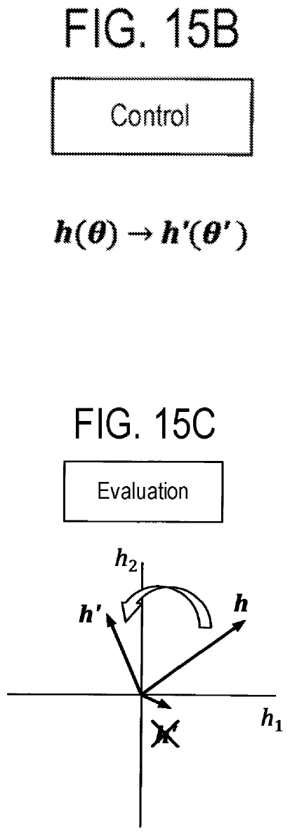

According to the process of step S24, even if the evaluation result is not as expected as shown in FIG. 14B, the control rule updater 212 may update the probability distribution of the value of each coefficient as shown in FIG. 14C using Bayes' theorem based on an event that is not as expected. FIGS. 14A to 14C are explanatory views of examples in which the probability distribution (prior distribution) of the value of each coefficient in the learning model that defines the control rule is updated.

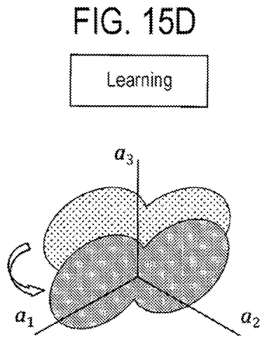

The processes of steps S18 to S24 in FIG. 4 are repeated until the process ends. According to the processes of the flowchart shown in FIG. 4, the control device 3 may improve the accuracy of the learning model by repeating processes shown in FIGS. 15A to 15D. FIGS. 15A to 15D are explanatory views of examples of a process of repeatedly controlling the electron energy distribution function of plasma by repeating learning of the control rule.

FIG. 15A shows the measurement of the electron energy distribution function of plasma during the plasma processing. FIG. 15B shows the control of the plasma processing according to the changed process parameter θ′. FIG. 15C shows the evaluation of the electron energy distribution function of plasma during the plasma processing by the changed process parameters θ′. FIG. 15D shows the process of learning the value of each coefficient in the learning model using Bayes' theorem based on the evaluation result.

As described above, according to this embodiment, the ideal electron energy distribution function, the evaluation function, and the learning model described above are defined, the electron energy distribution function of plasma during the plasma processing is measured, for example, in real time, and the measured electron energy distribution function of plasma may be evaluated using the evaluation function. The control device 3 may update the process parameters such that the electron energy distribution function of plasma approaches the ideal electron energy distribution function according to the learning model. The control device 3 may update each coefficient in the learning model according to Bayes' theorem to improve the accuracy of the learning model.

Since Bayes' theorem is used, the embodiment has an effect that an amount of calculation does not increase indefinitely. Further, in the embodiment, the control rule may be continuously learned by a daily plasma processing. Thus, there is no need to perform experimentally the plasma processing only for the purpose of learning.

According to the embodiment, while the electron energy distribution function of plasma during the plasma processing is measured in real time, the process parameters may be changed and the electron energy distribution function of plasma may be controlled. In addition, even if response characteristics of the electron energy distribution function of plasma are not clear with respect to the change in process parameters, in this embodiment, it is possible to optimize the control rule by learning the response characteristics of the electron energy distribution function of plasma for the change in process parameters through learning based on the evaluation result of the electron energy distribution function of plasma. Therefore, in this embodiment, the initial learning model received from the operator or the like by the control rule setting receiver 204 does not require high accuracy.

When plasma is ignited, a pressure value measured by the pressure gauge 160 may differ from an actual pressure value due to some phenomena occurring within the processing container 1. Therefore, in this embodiment, during the ignition of plasma, a degree of opening of the pressure control valve 151 may be used instead of the pressure value measured by the pressure gauge 160, included in the process parameters. This makes it possible to obtain a more stable electron energy distribution function, which implements a more desirable plasma processing.

In the plasma processing of the present disclosure using the electron energy distribution function, it is possible to implement an ideal plasma processing in real time by replacing ideal process results with the ideal electron energy distribution function without waiting for the measurement of process results which has been performed in the related art (measurement results obtained by using a measurement apparatus other than the plasma processing apparatus, such as a film thickness, a film quality, a shape and the like). Further, a time required when using other measurement apparatuses or resources (a wafer, gas, electric power, and the like) required to set process conditions may be reduced. Thus, the technique according to this embodiment is extremely useful.

While the preferable embodiments of the present disclosure have been described above, the present disclosure is not limited to the embodiments described above, and various modifications and substitutions may be made to the embodiments described above without departing from the scope of the present disclosure.

For example, in the above embodiment, the example in which one control device 3 is provided to correspond to one plasma processing apparatus 100 has been described, but one control device 3 may be provided to correspond to a plurality of plasma processing apparatuses 100. Further, the above embodiment may also be applied to an information processing system that summarizes learning results obtained by the control device 3 as pieces of data. In such an information processing system, a control rule may be prepared according to, for example, a model, processing contents or the like of the plasma processing apparatus 100 based on the pieces of summarized data. The control rule may be distributed according to a respective model, a respective processing content or the like. Alternatively, instead of the electron energy distribution function, an electron energy probability function (EEPF) that corresponds to the electron energy distribution function may be used. Therefore, a technical content in which the electron energy distribution function is replaced with the electron energy probability function may also be included in the scope of the present disclosure.

Although the present disclosure has been described above based on the above embodiments, the present disclosure is not limited to the above embodiments, and various modifications may be made within the scope of the claims. This application claims priority based on Japanese Patent Application No. 2021-152599 filed with the Japan Patent Office on Sep. 17, 2021, and the entire disclosure of which is incorporated herein in its entirety by reference.

Aspects of the present disclosure are, for example, as follows.

<1>

A plasma processing apparatus includes a control device and is configured to plasmarize a gas supplied to an interior of a processing container to perform a plasma processing on an object to be processed,
wherein the control device includes:
a measurer configured to measure an electron energy distribution function of plasma in the interior of the processing container; and a parameter changer configured to change parameters relating to the plasma processing so that the electron energy distribution function measured by the measurer during the plasma processing approaches a target electron energy distribution function.
   <2>

The plasma processing apparatus of <1> above further includes: a target setting receiver configured to receive a setting of an ideal electron energy distribution function during the plasma processing as the target electron energy distribution function.

<3>

The plasma processing apparatus of <2> above further includes: an evaluation function setting receiver configured to receive a setting of an evaluation function that quantifies a discrepancy between the electron energy distribution function measured during the plasma processing and the ideal electron energy distribution function during the plasma processing.

<4>

The plasma processing apparatus of <3> above further includes: a control rule setting receiver configured to receive a setting of a learning model which represents a correspondence between the parameters relating to the plasma processing and the discrepancy.

<5>

In the plasma processing apparatus of <4> above, the parameter changer changes the parameters relating to the plasma processing according to the learning model so that the discrepancy becomes smaller.

<6>

The plasma processing apparatus of <4> or <5> above further includes: a control rule updater configured to update the learning model based on an evaluation result of the electron energy distribution function during the plasma processing with the changed parameters by the evaluation function.

<7>

In the plasma processing apparatus of <6> above, the control rule updater updates a probability distribution of a coefficient value of the learning model according to Bayes' theorem based on the evaluation result by the evaluation function.

<8>

In the plasma processing apparatus of any one of <1> to <7> above, the parameters relating to the plasma processing are at least one of an input power, a frequency of the input power, a duty ratio of an input power pulse, a gas mixture ratio, a pressure, a temperature, a cumulative number of processes, a recent process recipe, or a recently-measured electron energy distribution function.

<9>

In the plasma processing apparatus of <8> above, the pressure included in the parameters relating to the plasma processing during ignition of the plasma uses a degree of opening of a pressure control valve instead of a pressure value measured by a pressure gauge.

<10>

In the plasma processing apparatus of any one of <1> to <9> above, an electron energy probability function corresponding to the electron energy distribution function is used instead of the electron energy distribution function.

<11>

A method controls a plasma processing apparatus including a control device and configured to plasmarize a gas supplied to an interior of a processing container to perform plasma processing on an object to be processed,
wherein the control device performs operations of:
measuring an electron energy distribution function of plasma in the interior of the processing container; and
changing parameters relating to the plasma processing so that the electron energy distribution function measured during the plasma processing approaches a target electron energy distribution function.
   <12>

A program for executing, in a control device configured to control a plasma processing apparatus which plasmarizes a gas supplied to an interior of a processing container to perform plasma processing on an object to be processed, a procedure of
measuring an electron energy distribution function of plasma in the interior of the processing container; and
changing parameters relating to the plasma processing so that the electron energy distribution function measured during the plasma processing approaches a target electron energy distribution function.

### EXPLANATION OF REFERENCE NUMERALS

1: processing container, 2: microwave plasma source, 3: control device, 70: plasma probe device, 100: plasma processing apparatus, 200: target setting receiver, 202: evaluation function setting receiver, 204: control rule receiver, 206: plasma processing controller, 208: electron energy distribution function measurer, 210: parameter changer, 212: control rule updater, 220: target storage, 222: evaluation function storage, 224: control rule storage, 226: process recipe storage

1.-12. (canceled)

13. A plasma processing apparatus comprising a control device and configured to plasmarize a gas supplied to an interior of a processing container to perform a plasma processing on an object to be processed,
wherein the control device includes:
a measurer configured to measure an electron energy distribution function of plasma in the interior of the processing container; and
a parameter changer configured to change parameters relating to the plasma processing so that the electron energy distribution function measured by the measurer during the plasma processing approaches a target electron energy distribution function.

14. The plasma processing apparatus of claim 13, further comprising: a target setting receiver configured to receive a setting of an ideal electron energy distribution function during the plasma processing as the target electron energy distribution function.

15. The plasma processing apparatus of claim 14, further comprising: an evaluation function setting receiver configured to receive a setting of an evaluation function that quantifies a discrepancy between the electron energy distribution function measured during the plasma processing and the ideal electron energy distribution function during the plasma processing.

16. The plasma processing apparatus of claim 15, further comprising: a control rule setting receiver configured to receive a setting of a learning model which represents a correspondence between the parameters relating to the plasma processing and the discrepancy.

17. The plasma processing apparatus of claim 16, wherein the parameter changer changes the parameters relating to the plasma processing according to the learning model so that the discrepancy becomes smaller.

18. The plasma processing apparatus of claim 17, further comprising: a control rule updater configured to update the learning model based on an evaluation result of the electron energy distribution function during the plasma processing with the changed parameters by the evaluation function.

19. The plasma processing apparatus of claim 18, wherein the control rule updater updates a probability distribution of a coefficient value of the learning model according to Bayes' theorem based on the evaluation result by the evaluation function.

20. The plasma processing apparatus of claim 13, wherein the parameters relating to the plasma processing are at least one of an input power, a frequency of the input power, a duty ratio of an input power pulse, a gas mixture ratio, a pressure, a temperature, a cumulative number of processes, a recent process recipe, or a recently-measured electron energy distribution function.

21. The plasma processing apparatus of claim 20, wherein, during ignition of the plasma, a degree of opening of a pressure control valve is used instead of the pressure measured by a pressure gauge, which is included in the parameters relating to the plasma processing.

22. The plasma processing apparatus of claim 13, wherein an electron energy probability function corresponding to the electron energy distribution function is used instead of the electron energy distribution function.

23. The plasma processing apparatus of claim 16, further comprising: a control rule updater configured to update the learning model based on an evaluation result of the electron energy distribution function during the plasma processing with the changed parameters by the evaluation function.

24. A method of controlling a plasma processing apparatus including a control device and configured to plasmarize a gas supplied to an interior of a processing container to perform plasma processing on an object to be processed,
wherein the control device performs operations of:
measuring an electron energy distribution function of plasma in the interior of the processing container; and
changing parameters relating to the plasma processing so that the electron energy distribution function measured during the plasma processing approaches a target electron energy distribution function.

25. A non-transitory computer-readable recording medium storing a program for executing, in a control device configured to control a plasma processing apparatus which plasmarizes a gas supplied to an interior of a processing container to perform plasma processing on an object to be processed, a procedure of:
measuring an electron energy distribution function of plasma in the interior of the processing container; and
changing parameters relating to the plasma processing so that the electron energy distribution function measured during the plasma processing approaches a target electron energy distribution function.
